(19) United States
(12) Patent Application Publication
(10) Pub. No.: US 2007/0222650 A1
(43) Pub. Date: Sep. 27, 2007

(54) Serial interface circuit and apparatus including serial interface circuit

(76) Inventors: Joonbae Park, Seoul (KR); Kyeongho Lee, Seoul (KR)

Correspondence Address: THE FLESHNER GROUP, PLLC, P.O. BOX 1397, ASHBURN, VA, 20146-9998, US

(21) Appl. No.: 11/724,320

(22) Filed: Mar. 15, 2007

(30) Foreign Application Priority Data
Mar. 17, 2006 (KR) 10-2006-0024669

(51) Int. Cl. H03M 9/00

(52) U.S. Cl. 341/100

(57) ABSTRACT

Embodiments include a serial interface circuit, serial interface method and an apparatus including a serial interface circuit. Embodiments of a serial interface circuit can include a frequency divider implemented by using a counter instead of a PLL. One embodiment of a serial interface circuit can include a data receiver to receive first serial data, a serial-parallel converter to convert the first serial data from the data receiver to first parallel data, a clock receiver to receive a first clock signal having a frequency corresponding to the first serial data, and a frequency divider coupled to the clock receiver to generate a second clock signal having a frequency corresponding to the first parallel data with the first clock signal where the frequency divider is configured with a counter.

### BACKGROUND

1. Field

The present invention relates to a serial interface circuit and an apparatus including a serial interface circuit.

2. Background

An analog-to-digital converter (ADC) and a digital-to-analog converter (DAC) have been used in electronic fields. An analog-to-digital converter (ADC) and a digital-to-analog converter (DAC) have been used to convert digital transmission data outputted from a base band processor and the like to analog transmission data or to convert analog reception data to digital reception data to be transmitted to the base band processor in a communication system.

However, the ADC and DAC have been manufactured as a separate chip from a chip including the base band processor and then sold. Therefore, there has been a disadvantage in that a lot of wiring is required to exchange information between a chip (referred to as an “analog chip”) including the ADC and DAC and a chip (referred to as a “digital chip”) including the base band processor. For example, if transmission data include I (in-phase) channel transmission data and Q (quadrature) channel transmission data; reception data contain I channel reception data and Q channel reception data; and the ADC and DAC are a 10 bit ADC and a 10 bit DAC, respectively, then 40 lines between the analog chip and the digital chip are required to transmit data. Accordingly, the number of pins of the analog chip and the digital chip has to be increased and the design of a PCB (printed circuit board) is complicated, thereby increasing the manufacturing cost.

The above references are incorporated by reference herein where appropriate for appropriate teachings of additional or alternative details, features and/or technical background.

### BRIEF DESCRIPTION OF THE DRAWINGS

Embodiments will be described in detail with reference to the following drawings in which like reference numerals refer to like elements wherein:

FIG. 1 is a diagram of a serial interface circuit and an apparatus including the serial interface circuit in accordance with an embodiment of the application; and

FIG. 2 shows a diagram of an example of a frequency divider shown in FIG. 1.

### DETAILED DESCRIPTION

Embodiments of a serial interface circuit and an apparatus including a serial interface circuit can convert data to serial data and transmit the serial data when the data have to be transmitted between an analog chip and a digital chip to decrease the number of pins of the chip or reduce the complexity of a PCB design.

Embodiments will be described with reference to the accompanying drawings. Such embodiments are exemplary and not to be construed as limiting embodiments in the application. Many alternatives, modifications, and variations will be apparent to those skilled in the art.

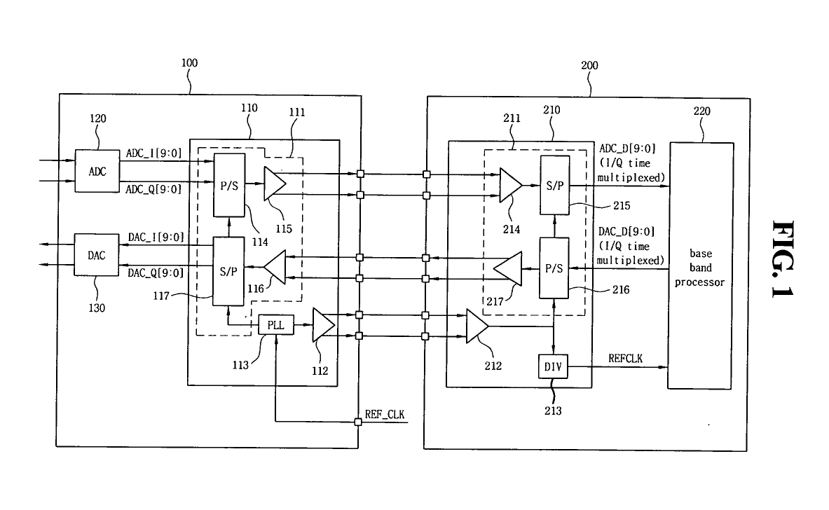

FIG. 1 is a diagram of an embodiment of a serial interface circuit and an embodiment of an apparatus including the serial interface circuit in accordance with the application. As shown in FIG. 1, the apparatus embodiment can include an analog chip 100 and a digital chip 200. The analog chip 100 can include a first interface circuit 110, an ADC 120 and a DAC 130. The digital chip 200 can include a second interface circuit 210 and a base band processor 220.

The first interface circuit 110 can include a first data transceiver 111 and a clock transmitter 112. Moreover, the first interface circuit 110 can further include a PLL (phase locked loop) 113.

The first data transceiver 111 can convert first parallel ADC data (e.g., ADC_I[9:0], ADC_Q[9:0]) provided by the ADC 120 to a serial ADC data and then transmit the serial ADC data to a second data transceiver 211. Further, the first data transceiver 111 can convert a serial DAC data transmitted from the second data transceiver 211 to first parallel DAC data (e.g., DAC_I[9:0], DAC_Q[9:0]) and then transmit the first parallel DAC data to the DAC 130. The first data transceiver 111 can include an ADC parallel-serial converter 114, an ADC transmitter 115, a DAC receiver 116 and a DAC serial-parallel converter 117.

The ADC parallel-serial converter 114 can convert the first parallel ADC data (e.g., ADC_I[9:0], ADC_Q[9:0]) to the serial ADC data. The ADC transmitter 115 sends the serial ADC data outputted from the ADC parallel-serial converter 114 to the second data transceiver 211. The DAC receiver 116 receives the serial DAC data transmitted from the second data transceiver 211. The DAC serial-parallel converter 117 can convert the serial DAC data outputted from the DAC receiver 116 to the first parallel DAC data (e.g., DAC_I[9:0], DAC_Q[9:0]) and then transmit the first parallel DAC data to the DAC 130.

In one exemplary embodiment, the ADC transmitter 115 and the DAC receiver 116 carry out a transmission and a reception by using an LVDS (low voltage differential signaling) method, respectively. However, embodiments of the invention are not intended to be so limited as other methods may be used. In case of using the LVDS method, two lines are required to transmit each serial data as shown in FIG. 1 because a differential signal has to be transmitted.

The clock transmitter 112 can transmit a first clock signal having a frequency corresponding to a frequency of the serial ADC data and the serial DAC data to a clock receiver 212. In one exemplary embodiment, the clock transmitter 112 performs a transmission by using the LVDS method. The first clock signal having the frequency corresponding to the frequency of the serial ADC data and the serial DAC data can mean that the ADC data and the DAC data will be latched by using one or all of a rising edge and a falling edge of the first clock signal. For example, the frequency of the first clock signal is the same as the frequency of the serial ADC data and the serial DAC data or 0.5 times the frequency of the serial ADC data and the serial DAC data.

The PLL 113 can generate the first clock signal by using a third clock signal REF_CLK and then can transmit the generated first clock signal to the first data transceiver 111 and the clock transmitter 112.

The second interface circuit 210 can include the second data transceiver 211, the clock receiver 212 and a frequency divider 213.

The second data transceiver 211 can convert the serial ADC data provided by the first data transceiver 111 to second parallel ADC data (e.g., ADC_D[9:0]) and then can transmit the second parallel ADC data to the base band processor 220. Further, the second data transceiver 211 can convert second parallel DAC data (e.g., DAC_D[9:0]) to the serial DAC data and then transmit the serial DAC data to the first data transceiver 111. The second data transceiver 211 can include an ADC receiver 214, an ADC serial-parallel converter 215, a DAC parallel-serial converter 216 and a DAC transmitter 217. The ADC receiver 214 can receive the serial ADC data transmitted from the first data transceiver 111. The ADC serial-parallel converter 215 can convert the serial ADC data received by the ADC receiver 214 to the second parallel ADC data (e.g., ADC_D[9:0]) and then transmit the second parallel ADC data to the base band processor 220. The DAC parallel-serial converter 216 can convert the second parallel DAC data (e.g., DAC_D[9:0]) transmitted by the base band processor 220 to the serial DAC data. The DAC transmitter 217 can transmit the serial DAC data outputted from the DAC parallel-serial converter 216 to the first data transceiver 111. In one exemplary embodiment, the ADC receiver 214 and the DAC transmitter 217 perform a reception and a transmission by using the LVDS method, respectively. The second parallel ADC data (e.g., ADC_D[9:0]) and the second parallel DAC data (e.g., DAC_D[9:0]) can be I/Q multiplexed and transmitted, respectively, as shown in FIG. 1. However, embodiments of the invention are not intended to be so limited, for example, data can also be transmitted in the form of 20 bit parallel data without multiplexing, respectively.

The clock receiver 212 can receive the first clock signal delivered by the clock transmitter 112 and can then provide the second data transceiver 211 and the frequency divider 213 with the first clock signal. In one exemplary embodiment, the clock receiver 212 performs a reception by using the LVDS method.

The frequency divider 213 can generate a second clock signal REFCLK having a frequency corresponding to a frequency of the second parallel ADC data (e.g., ADC_D[9:0]) and the second parallel DAC data (e.g., DAC_D[9:0]) by using the first clock signal received by the clock receiver 212, and then can transmit the second clock signal REFCLK to the base band processor 220. The second clock signal REFCLK having the frequency corresponding to the frequency of the second parallel ADC data (e.g., ADC_D[9:0]) and the second parallel DAC data (e.g., DAC_D[9:0]) can mean that the second parallel ADC data (e.g., ADC_D[9:0]) and the second parallel DAC data (e.g., DAC_D[9:0]) can be latched by using one or all of a rising edge and a falling edge of the second clock signal REFCLK. For example, the frequency of the second clock signal REFCLK is the same as the frequency of the second parallel ADC data and the second parallel DAC data or 0.5 times the frequency of the second parallel ADC data and the second parallel DAC data. The frequency divider 213 can be implemented by using a counter instead of the PLL.

The second data transceiver 211 may perform only a function of converting the serial ADC data provided by the first data transceiver 111 to the second parallel ADC data (e.g., ADC_D[9:0]) and transmitting the second parallel ADC data to the base band processor 220. In such an embodiment, the second data transceiver 211 can include the ADC receiver 214 and the ADC serial-parallel converter 215 and the frequency divider 213, which can generate the second clock signal REFCLK having the frequency corresponding to the frequency of the second parallel ADC data (e.g., ADC_D[9:0]) by using the first clock signal received by the clock receiver 212 and transmit the second clock signal REFCLK to the base band processor 220.

Further, the second data transceiver 211 can perform only a function of converting the second parallel DAC data PAC_D[9:0]) provided by the base band processor 220 to the serial DAC data and transmitting the serial DAC data to the first data transceiver 111. In such an embodiment, the second data transceiver 211 can include the DAC parallel-serial converter 216 and the DAC transmitter 217 and the frequency divider 213, which can generate the second clock signal REFCLK having the frequency corresponding to the frequency of the second parallel DAC data (e.g., DAC_D[9:0]) by using the first clock signal received by the clock receiver 212 and transmit the second clock signal REFCLK to the base band processor 220.

The base band processor 220 is a processor configured to perform a function of base band processing. However, the second parallel ADC data (e.g., ADC_D[9:0]) to be inputted to the base band processor 220 and the second parallel DAC data (e.g., DAC_D[9:0]) to be outputted from the base band processor 220 do not need to be a base band signal but can, for example, be an intermediate frequency signal.

When converting the data to serial data to transmit, a clock signal having a frequency corresponding a frequency of the serial data is transmitted from the analog chip to the digital chip and then the digital chip needs to restore a clock signal having a frequency corresponding to a frequency of parallel data by using the transmitted clock signal. However, when a frequency divider for restoring the clock signal having the frequency corresponding to the frequency of the parallel data by using the clock signal having the frequency corresponding to the frequency of the serial data is implemented by using a PLL (phase locked loop), there is a disadvantage because the PLL occupies a large area and consumes an enormous amount of power. Particularly, the above-described disadvantages or problems are serious for a wireless terminal such as a cellular phone and the like since the wireless terminal requires a small hardware and a low power consumption.

Therefore, one embodiment is configured to provide a serial interface circuit and an apparatus including a serial interface circuit that can implement a frequency divider using a counter instead of the PLL to reduce complexity or the cost of the frequency divider.

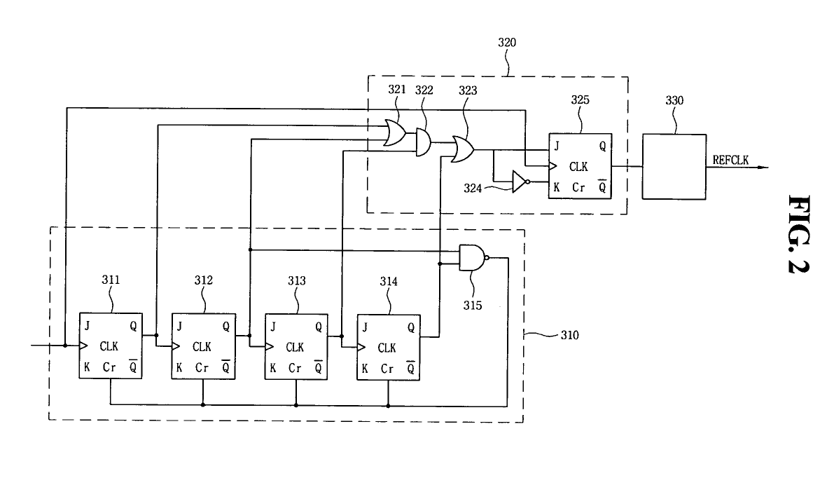

FIG. 2 shows a diagram of an exemplary embodiment of the frequency divider. The frequency divider of FIG. 2 can be used in the embodiment of FIG. 1. However, embodiments are not intended to be so limited. For example, the frequency divider embodiment shown in FIG. 2 is an example of an asynchronous counter. However, the frequency divider shown in FIG. 2 can be implemented by using various counters such as a synchronous counter instead of the asynchronous counter.

As shown in FIG. 2, the frequency divider can include a counter unit 310, a clock generator 320 and a buffer 330. The counter unit 310 can perform a function of counting the number of clocks of the first clock signal. The counter unit 310 shown in FIG. 2 is a decimal asynchronous counter and includes first to fourth JK flip-flops 311 to 314 and a NAND gate 315. The NAND gate 315 can clear the first to fourth JK flop-flops 311 to 314, for example as shown in FIG. 2, when the second and the fourth JK flip-flops 312 and 314 output “1”.

The clock generator 320 can generate a clock signal having a frequency which is 0.1 times the first clock signal frequency by using the output of the counter unit 310. The clock generator 320 may include logic circuits 321 to 324 and a JK flip-flop 325.

The buffer 330 can generate the second clock signal REFCLK having a driving power larger than that of the clock signal outputted from the clock generator 320 and having the frequency which is 0.1 times the first clock signal frequency.

Embodiments of the invention have various advantages. For example, embodiments of a serial interface circuit or an apparatus including the serial interface circuit can convert data to serial data and then transmit the serial data when the data have to be transmitted between the analog chip and the digital chip. Thus, the number of pins of the chip can be decreased or the complexity of a PCB (e.g., design) can be reduced. Embodiments of a serial interface circuit and an apparatus including the serial interface circuit can implement a frequency divider by using a counter instead of a PLL, which can reduce the complexity, power consumption and/or the cost of the frequency divider.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Embodiments of a serial interface circuit, a method of operating and/or an apparatus including the same can include a frequency divider implemented using a counter.

To achieve objects of embodiments of the application in whole or in part, there is provided serial interface circuit that can include a data receiver configured to receive first serial data, a serial-parallel converter configured to convert the first serial data from the data receiver to first parallel data, a clock receiver configured to receive a first clock signal having a frequency corresponding to the first serial data and a frequency divider configured to generate a second clock signal having a frequency corresponding to the first parallel data by using the first clock signal received by the clock receiver, wherein the frequency divider is implemented using a counter.

To achieve objects of embodiments of the application in whole or in part, there is provided serial interface circuit that can include a parallel-serial converter to convert parallel data to serial data, a data transmitter to transmit the serial data, a clock receiver to receive a first clock signal having a frequency corresponding to the serial data and a frequency divider to generate a second clock signal having a frequency corresponding to the parallel data by using the first clock signal received by the clock receiver, wherein the frequency divider is implemented by using a counter.

To achieve objects of embodiments of the application in whole or in part, there is provided an apparatus that can include a first chip including an ADC, a DAC and a first interface circuit and a second chip including a base band processor and a second interface circuit, wherein the first interface circuit includes a first data transceiver and a clock transmitter, and the second interface circuit comprises a second data transceiver, a clock receiver and a frequency divider, the first data transceiver to convert first parallel ADC data from the ADC to serial ADC data and transmit the serial ADC data to the second data transceiver, and to convert serial DAC data from the second data transceiver to first parallel DAC data and transmit the parallel DAC data to the DAC, the clock transmitter to transmit a first clock signal having a frequency corresponding to a frequency of the serial ADC data and the serial DAC data to the clock receiver, the second data transceiver to convert the serial ADC data from the first data transceiver to second parallel ADC data and transmit the second parallel ADC data to the base band processor, and to convert second parallel DAC data from the base band processor to serial DAC data and transmit the DAC data to the first data transceiver, the clock receiver to receive the first clock signal from the clock transmitter, the frequency divider to generate a second clock signal having a frequency corresponding to the second parallel ADC data and the second parallel DAC data with the first clock signal received by the clock receiver, and the frequency divider configured with a counter.

To achieve objects of embodiments of the application in whole or in part, there is provided a method of operating serial interface circuit between a first chip with an ADC, a DAC and a first interface circuit having a first data transceiver and a clock transmitter and a second chip with a base band processor and a second interface circuit having a second data transceiver, a clock receiver and a frequency divider, the method including converting first parallel ADC data from the ADC to serial ADC data and transmitting the serial ADC data to the second data transceiver using the first data transceiver, converting serial DAC data from the second data transceiver to first parallel DAC data and transmitting the parallel DAC data to the DAC using the first data transceiver, transmitting a first clock signal having a frequency corresponding to a frequency of the serial ADC data and the serial DAC data to the clock receiver using the clock transmitter, converting the serial ADC data from the first data transceiver to second parallel ADC data and transmitting the second parallel ADC data to the base band processor using the second data transceiver, converting second parallel DAC data from the base band processor to serial DAC data and transmitting the DAC data to the first data transceiver using the second data transceiver, receiving the first clock signal from the clock transmitter and generating a second clock signal having a frequency corresponding to the second parallel ADC data and the second parallel DAC data with the first clock signal received by the clock receiver using the frequency divider configured with a counter.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A serial interface circuit, comprising:
a data receiver configured to receive first serial data;
a serial-parallel converter configured to convert the first serial data from the data receiver to first parallel data;
a clock receiver configured to receive a first clock signal having a frequency corresponding to the first serial data; and
a frequency divider configured to generate a second clock signal having a frequency corresponding to the first parallel data by using the first clock signal received by the clock receiver, wherein the frequency divider is implemented using a counter.

2. The serial interface circuit of claim 1, further comprising:
a parallel-serial converter configured to convert second parallel data to second serial data; and
a data transmitter configured to transmit the second serial data.

3. The serial interface circuit of claim 2, wherein the data receiver operates using an low voltage differential signaling format to receive the first serial data,
the data transmitter is configured to transmit the second serial data by using the low voltage differential signaling format, and
the clock receiver configured to receive the first clock signal by using the low voltage differential signaling format.

4. The serial interface circuit of claim 2, wherein the frequency divider includes:
a counter configured to count the number of clocks of the first clock signal received by the clock receiver;
a clock generator configured to generate a clock signal having a frequency corresponding to the first parallel data using the output of the counter; and
a buffer configured to output the second clock signal with a driving power larger than that of the clock signal outputted from the clock generator and having the frequency corresponding to the first parallel data.

5. The serial interface circuit of claim 1, wherein the frequency divider does not include a phase locked loop (PLL) circuit.

6. A serial interface circuit, comprising:
a parallel-serial converter to convert parallel data to serial data;
a data transmitter to transmit the serial data;
a clock receiver to receive a first clock signal having a frequency corresponding to the serial data; and
a frequency divider to generate a second clock signal having a frequency corresponding to the parallel data by using the first clock signal received by the clock receiver, wherein the frequency divider is implemented by using a counter.

7. The serial interface circuit of claim 6, wherein the frequency divider includes:
a counter configured to count the number of clocks of the first clock signal received by the clock receiver;
a clock generator configured to generate a clock signal having a frequency corresponding to the first parallel data using the output of the counter; and
a buffer configured to output the second clock signal with a driving power larger than that of the clock signal outputted from the clock generator and having the frequency corresponding to the first parallel data.

8. The serial interface circuit of claim 6, wherein the frequency divider does not include a phase locked loop (PLL) circuit.

9. An apparatus, comprising:
a first chip including an ADC, a DAC and a first interface circuit; and
a second chip including a base band processor and a second interface circuit,
wherein the first interface circuit comprises a first data transceiver and a clock transmitter, and
the second interface circuit comprises a second data transceiver, a clock receiver and a frequency divider,
the first data transceiver to convert first parallel ADC data from the ADC to serial ADC data and transmit the serial ADC data to the second data transceiver, and to convert serial DAC data from the second data transceiver to first parallel DAC data and transmit the parallel DAC data to the DAC,
the clock transmitter to transmit a first clock signal having a frequency corresponding to a frequency of the serial ADC data and the serial DAC data to the clock receiver,
the second data transceiver to convert the serial ADC data from the first data transceiver to second parallel ADC data and transmit the second parallel ADC data to the base band processor, and to convert second parallel DAC data from the base band processor to serial DAC data and transmit the DAC data to the first data transceiver,
the clock receiver to receive the first clock signal from the clock transmitter,
the frequency divider to generate a second clock signal having a frequency corresponding to the second parallel ADC data and the second parallel DAC data with the first clock signal received by the clock receiver, and the frequency divider configured with a counter.

10. The apparatus of claim 9, wherein the first interface circuit comprises a PLL to generate the first clock signal by using a third clock signal having a predetermined frequency to transmit the first clock signal to the first data transceiver and the clock transmitter.

11. The apparatus of claim 9, wherein the second data transceiver comprises:
an ADC receiver to receive the serial ADC data from the first data transceiver;
an ADC serial-parallel converter to convert the serial ADC data received by the ADC receiver to the second parallel ADC data and transmit the ADC data to the base band processor;
a DAC parallel-serial converter to convert the second parallel DAC data provided by the base band processor to the serial DAC data; and
a DAC transmitter to transmit the serial DAC data outputted from the DAC parallel-serial converter to the first data transceiver.

12. The apparatus of claim 11, wherein the first data transceiver comprises:
an ADC parallel-serial converter to convert the first parallel ADC data to the serial ADC data;
an ADC transmitter to transmit the serial ADC data outputted from the ADC parallel-serial converter to the second data transceiver;
a DAC receiver to receive the serial DAC data transmitted from the second data transceiver; and
a DAC serial-parallel converter to convert the serial DAC data received by the DAC receiver to the first parallel DAC data to transmit the first parallel DAC data to the DAC.

13. The apparatus of claim 12, wherein the clock transmitter and the clock receiver are configured to perform a transmission and a reception using an low voltage differential signaling (LVDS) method,
the ADC transmitter and the ADC receiver are configured to perform a transmission and a reception using the LVDS method, and
the DAC transmitter and the DAC receiver are configured to perform a transmission and a reception by using the LVDS method.

14. The serial interface circuit of claim 9, wherein the frequency divider includes:
a counter configured to count the number of clocks of the first clock signal received by the clock receiver;
a clock generator configured to generate a clock signal having a frequency corresponding to the first parallel data using the output of the counter; and
a buffer configured to output the second clock signal with a driving power larger than that of the clock signal outputted from the clock generator and having the frequency corresponding to the first parallel data.

15. The apparatus of claim 9, wherein frequency divider does not include a phase locked loop circuit.
